(19) United States
(12) Patent Application Publication
(10) Pub. No.: US 2026/0302131 A1
(43) Pub. Date: Oct. 1, 2026

(54) CHARGED PARTICLE BEAM DEVICE AND CONTROL METHOD THEREFOR

(71) Applicant: Hitachi, Ltd., Tokyo (JP)

(72) Inventors: Fumiaki ICHIHASHI, Tokyo (JP); Toshiaki TANIGAKI, Tokyo (JP)

(21) Appl. No.: 19/530,790

(22) Filed: Feb. 5, 2026

(30) Foreign Application Priority Data
Mar. 28, 2025 (JP) 2025-054737

(51) Int. Cl. H01J 37/304; H01J 37/305

(52) U.S. Cl. CPC H01J 37/304; H01J 37/305; H01J 2237/24495

(57) ABSTRACT

A charged particle beam device includes a sample holder that holds a sample, an ion source that emits a focused ion beam with which the sample is irradiated, a secondary electron detection unit that detects secondary electrons emitted from the sample by irradiation with the focused ion beam, and a control unit that generates an observation image of the sample based on a detection signal output from the secondary electron detection unit and controls each unit. The control unit receives an amount of shape change, when the sample is subjected to test milling using the focused ion beam, and a target shape after milling of the sample. The amount of shape change and the target shape are input to a training model generated by performing machine training in advance.

### CROSS-REFERENCE TO RELATED APPLICATION

The present application claims priority from Japanese Patent Application JP 2025-054737 filed on Mar. 28, 2025, the content of which is hereby incorporated by reference into this application.

### BACKGROUND OF THE INVENTION

### 1. Technical Field

The present invention relates to a charged particle beam device.

### 2. Description of the Related Art

An FIB-SEM device including a focused-ion-beam (FIB) irradiation device and a scanning electron microscope (SEM) is used for preparation of a sample that has been made into a thin piece and is used for observation with a transmission electron microscope (TEM). That is, by repeating milling of the sample by FIB irradiation and SEM observation of the milled sample, a thinly sliced sample is prepared. In the FIB-SEM device, automation and accuracy of sample preparation are improved.

Japanese Patent No. 7,407,906 discloses updating milling conditions such as a milling setting region and an acceleration voltage based on a result of evaluating a sample prepared by an FIB-SEM device by TEM observation. In addition, Japanese Patent No. 7,407,906 discloses that the milling end point is determined by inputting the SEM image being milled to a training model generated in advance by training the SEM image of the prepared sample and the TEM image in association with each other.

### SUMMARY OF THE INVENTION

However, Japanese Patent No. 7,407,906 does not consider an tilt angle of a sample during FIB milling. Since the FIB with which the sample is irradiated does not become a parallel beam but has a spread called flare, it is necessary to adjust the tilt angle of the sample during FIB milling.

Therefore, an object of the present invention is to provide a charged particle beam device capable of easily setting milling conditions including an tilt angle of a sample, and a method for controlling the charged particle beam device.

In order to achieve the above object, the present invention provides a charged particle beam device including: a sample holder that holds a sample; an ion source that emits a focused ion beam with which the sample is irradiated; a secondary electron detection unit that detects secondary electrons emitted from the sample by irradiation with the focused ion beam; and a control unit that generates an observation image of the sample based on a detection signal output from the secondary electron detection unit and controls each unit, in which the control unit receives an amount of shape change when the sample is subjected to test milling using the focused ion beam and a target shape after milling of the sample, the amount of shape change and the target shape are input to a training model generated by performing machine training in advance on a relationship between a milling condition including an tilt angle of a milled surface of the sample with respect to a central axis of the focused ion beam and a milling result including flatness of the milled surface, and a milling condition including the tilt angle is output.

Further, the present invention provides a control method of a charged particle beam device, the charged particle beam device including a sample holder that holds a sample, an ion source that emits a focused ion beam with which the sample is irradiated, a secondary electron detection unit that detects secondary electrons emitted from the sample by irradiation with the focused ion beam, and a control unit that generates an observation image of the sample based on a detection signal output from the secondary electron detection unit and controls each unit, the control method including setting an tilt angle by inputting an amount of shape change when the sample is subjected to test milling using the focused ion beam and a target shape after milling of the sample to a training model generated by performing machine training in advance on a relationship between a milling condition including the tilt angle of a milled surface of the sample with respect to a central axis of the focused ion beam and a milling result including flatness of the milled surface.

Further, the present invention provides a charged particle beam device including: a sample holder that holds a sample; an ion source that emits a focused ion beam with which the sample is irradiated; a secondary electron detection unit that detects secondary electrons emitted from the sample by irradiation with the focused ion beam; an electron source that emits an electron beam with which the sample is irradiated; a backscattered electron detection unit that detects backscattered electrons emitted from the sample by irradiation with the electron beam; and a control unit that generates an observation image of the sample based on a detection signal output from the secondary electron detection unit or the backscattered electron detection unit and controls each unit, in which the control unit generates a training model by performing machine training on a relationship between a milling condition including an tilt angle of a milled surface of the sample with respect to a central axis of the focused ion beam and a milling result including flatness of the milled surface calculated based on a detection signal output from the backscattered electron detection unit.

According to the present invention, it is possible to provide a charged particle beam device capable of easily setting a milling condition including an tilt angle of a sample and a method for controlling the charged particle beam device.

### BRIEF DESCRIPTION OF THE DRAWINGS

FIG. 1 is a schematic configuration diagram of a charged particle beam device of a first embodiment;

FIG. 2 is a diagram illustrating an example of a flow of processing of the first embodiment;

FIG. 3 is a diagram illustrating an example of a screen to which a target shape is input;

FIG. 4 is a diagram illustrating an example of a screen on which milling conditions are displayed;

FIG. 5 is a diagram illustrating an example of a flow of processing of generating a training model; and

FIG. 6 is a diagram illustrating an example of a screen for setting machine training conditions.

### DETAILED DESCRIPTION

Hereinafter, a charged particle beam device of the present invention will be described with reference to the drawings. The charged particle beam device of the present invention is an FIB-SEM device including an FIB irradiation device and an SEM. Note that, in the following description and the accompanying drawings, components having the same functional configuration are denoted by the same reference numerals, and overlapping description is omitted. In addition, an XYZ coordinate system is added to each drawing to indicate the orientation of each drawing.

### First Embodiment

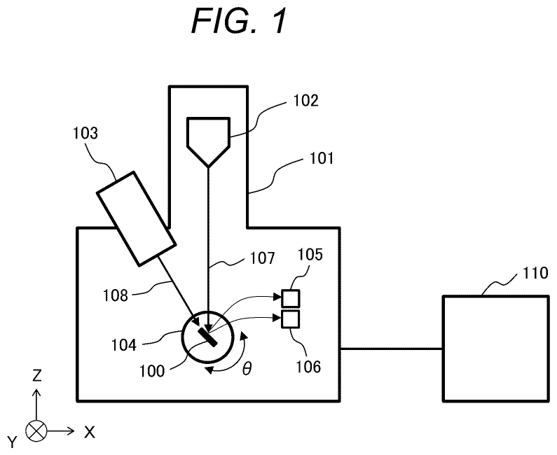

The FIB-SEM device which is a charged particle beam device of the first embodiment will be described with reference to FIG. 1. The FIB-SEM device illustrated in FIG. 1 includes a housing 101 and a control unit 110. The housing 101 includes an ion source 102, an electron source 103, a sample holder 104, a backscattered electron detection unit 105, and a secondary electron detection unit 106, and the inside thereof is evacuated.

The ion source 102 emits an FIB 107 with which a sample 100 is irradiated. The sample 100 is milled by irradiation with the FIB 107. The electron source 103 emits an electron beam 108 to be irradiated onto the sample 100. The sample holder 104 holds the sample 100, and adjusts an tilt angle θ of the sample 100 with respect to the center axes of the FIB 107 and the electron beam 108. The backscattered electron detection unit 105 detects backscattered electrons emitted from the sample 100 by irradiation with the electron beam 108 and outputs a detection signal. The secondary electron detection unit 106 detects secondary electrons emitted from the sample 100 by irradiation with the FIB 107 and outputs a detection signal.

The control unit 110 is a device that generates an observation image of the sample 100 based on the detection signal output from the backscattered electron detection unit 105 and the secondary electron detection unit 106, and controls each unit of the housing 101, and is a so-called computer. The observation image is displayed on a display device such as a liquid crystal display connected to the control unit 110. Note that the observation image generated based on the detection signal output from the backscattered electron detection unit 105 is a backscattered electron image, and the observation image generated based on the detection signal output from the secondary electron detection unit 106 is a scanning ion microscope (SIM) image.

By the way, since the FIB 107 with which the sample 100 is irradiated does not become a parallel beam but has a spread called flare, if the tilt angle θ of the milled surface of the sample 100 with respect to the center axis of the FIB 107 is not appropriately adjusted, the flatness of the milled surface deteriorates. Therefore, in the first embodiment, the flatness of the milled surface is improved by adjusting the tilt angle θ using a training model which is generated by machine-training in advance the relationship between the milling condition including the tilt angle θ of the milled surface of the sample 100 with respect to the central axis of the FIB 107 and the milling result including the flatness of the milled surface of the sample 100.

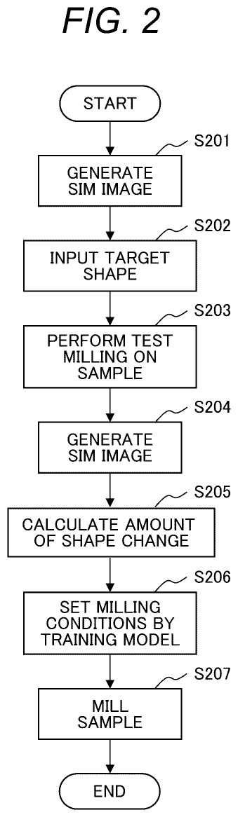

An example of the flow of processing in the first embodiment will be described step by step with reference to FIG. 2.

### (S201)

The control unit 110 generates a SIM image by irradiating the sample 100 with the FIB 107 from the ion source 102 and receiving a detection signal from the secondary electron detection unit 106 that detects secondary electrons. The SIM image generated in S201 represents the shape of the sample 100 before test milling.

### (S202)

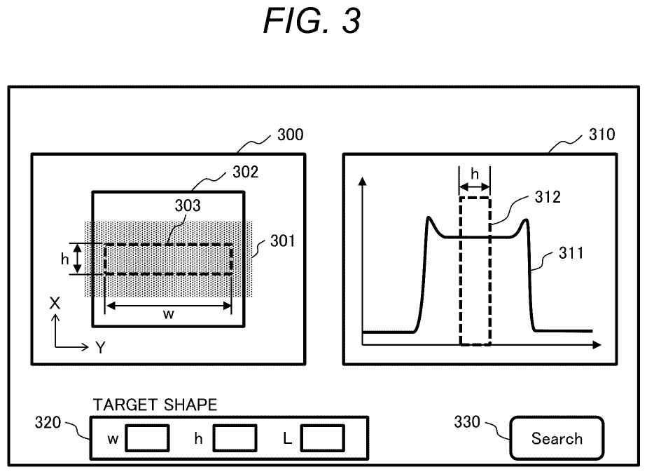

The operator inputs a target shape after milling. A screen illustrated in FIG. 3 may be used to input the target shape. The screen of FIG. 3 includes a SIM image display unit 300, an intensity profile display unit 310, a target shape input unit 320, and a button 330.

The SIM image display unit 300 displays a SIM image 301, an intensity profile acquisition region 302, and a target shape 303. The SIM image 301 is a SIM image of a plane orthogonal to the milled surface of the sample 100. The intensity profile acquisition region 302 is a region where the intensity profile of the SIM image 301 is acquired. The target shape 303 indicates a target shape input by the operator.

The intensity profile display unit 310 displays an intensity profile 311 and a target shape 312. The intensity profile 311 is an intensity profile acquired in the intensity profile acquisition region 302. The target shape 312 indicates a target shape input by the operator, the vertical length does not represent anything.

The numerical values of the length w in the Y direction, the length h in the X direction, and the length L in the Z direction are input to the target shape input unit 320 as target shapes. The shapes of the target shape 303 and the target shape 312 change according to the numerical values of w, h, and L input to the target shape input unit 320.

When the button 330 is pressed, the target shape input to the target shape input unit 320 is transmitted to the control unit 110. The description returns to FIG. 2.

### (S203)

The control unit 110 performs test milling of the sample 100 by irradiating the sample 100 with the FIB 107 from the ion source 102. The test milling is milling of slightly cutting one end of the sample 100. That is, the cutting amount by the test milling is extremely smaller than the cutting amount by the milling in S207. The irradiation condition of the FIB 107 at the time of test milling is set in advance. The irradiation conditions of the FIB 107 include an irradiation current density, an irradiation time, and the like.

### (S204)

Similarly to S201, the control unit 110 generates a SIM image by irradiating the sample 100 with the FIB 107 and receiving the detection signal from the secondary electron detection unit 106. The SIM image generated in S204 represents the shape of the sample 100 after the test milling.

### (S205)

The control unit 110 calculates the amount of shape change due to the test milling based on the SIM images generated in S201 and S204. The amount of shape change is calculated, for example, as a difference in the intensity profile before and after the test milling. Since the cutting amount by the test milling changes depending on the magnitude of the flare of the FIB 107, the influence of the flare of the FIB 107 is reflected in the amount of shape change.

### (S206)

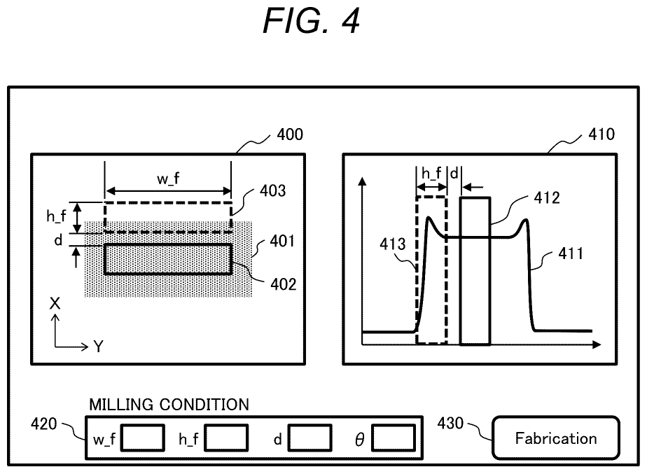

The control unit 110 sets the milling conditions including the tilt angle θ of the milled surface of the sample 100 with respect to the center axis of the FIB 107 by inputting the target shape in S202 and the amount of shape change in S205 to a training model generated in advance. The set milling condition is a condition for minimizing the flatness of the milled surface of the sample 100, and may be displayed on the screen illustrated in FIG. 4. The screen of FIG. 4 includes a SIM image display unit 400, an intensity profile display unit 410, a milling condition display unit 420, and a button 430.

The SIM image display unit 400 displays a SIM image 401, a target shape 402, and a milling region 403. The SIM image 401 is a SIM image of a plane orthogonal to the milled surface of the sample 100. The target shape 402 indicates a target shape input by the operator. The milling region 403 is a region irradiated with the FIB 107, has a length w_f in the Y direction and a length h_f in the X direction, and is set by the control unit 110. The distance d between the target shape 402 and the milling region 403 is also included in the milling conditions.

The intensity profile display unit 410 displays an intensity profile 411, a target shape 412, and a milling region 413. The intensity profile 411 is an intensity profile acquired from the SIM image 401. The target shape 412 indicates a target shape input by the operator, but the vertical length does not represent anything. The milling region 413 is a region irradiated with the FIB 107, has a length h_f in the X direction, and is set by the control unit 110. Note that the vertical length of the milling region 413 does not represent anything.

In the milling condition display unit 420, the respective numerical values of the length w_f in the Y direction and the length h_f in the X direction of the milling region 403, the distance d between the target shape 402 and the milling region 403, and the tilt angle θ of the milled surface of the sample 100 with respect to the central axis of the FIB 107 are displayed as milling conditions.

When the button 430 is pressed, the milling condition displayed on the milling condition display unit 420 is set, and a milling start signal of the sample 100 is transmitted to the control unit 110. The description returns to FIG. 2.

### (S207)

The control unit 110 mills the sample 100 by irradiation with the FIB 107 according to the milling conditions set in S206. Since the milling condition set in S206 is based on the amount of shape change reflecting the influence of the flare of the FIB 107, milling suitable for the state of the flare of the FIB 107 can be performed.

The milling conditions including the tilt angle θ of the milled surface of the sample 100 with respect to the central axis of the FIB 107 can be easily set by the flow of the processing described with reference to FIG. 2. In addition, since milling suitable for the flared state of the FIB 107 becomes possible, the flatness of the milled surface of sample 100 is minimized, and the milling accuracy can be improved. The flatness of the milled surface of the sample 100 may be calculated by the control unit 110 based on the backscattered electron image generated by the irradiation of the sample 100 with the electron beam 108 from the electron source 103 and the detection of the backscattered electrons by the backscattered electron detection unit 105. By calculating the flatness of the milled surface of the sample 100, it can be confirmed that milling is appropriate. In order to execute the flow of processing illustrated in FIG. 2, it is necessary to generate a training model in advance by machine training.

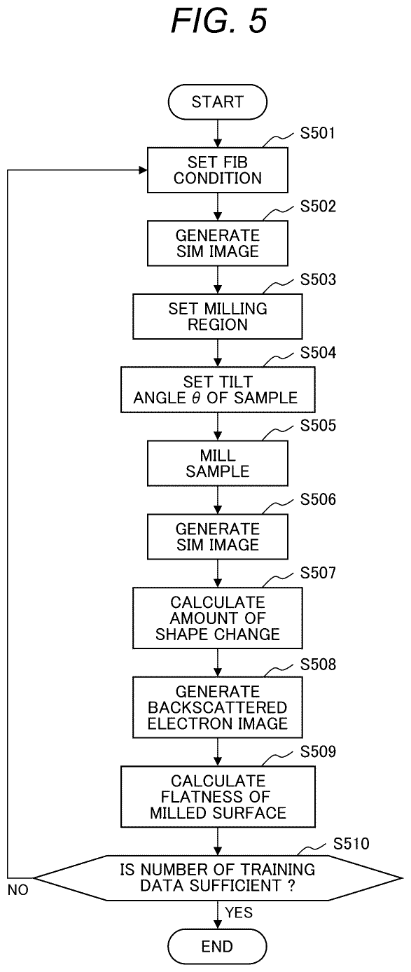

An example of the flow of processing of generating a training model will be described step by step with reference to FIG. 5.

### (S501)

The control unit 110 sets irradiation conditions of the FIB 107. The irradiation conditions of the FIB 107 include an irradiation current density, an irradiation time, and the like.

### (S502)

The control unit 110 generates a SIM image by irradiating the sample 100 with the FIB 107 from the ion source 102 and receiving a detection signal from the secondary electron detection unit 106 that detects secondary electrons emitted from the sample 100. The SIM image generated in S502 represents the shape of the sample 100 before milling.

### (S503)

The control unit 110 sets a milling region. That is, the length w_f in the Y direction and the length h_f in the X direction of the region irradiated with the FIB 107 are set by the control unit 110. A distance d between the target shape 402 and the milling region 403 is also set.

### (S504)

The control unit 110 sets an tilt angle θ of the milled surface of the sample 100 with respect to the central axis of the FIB 107.

### (S505)

The control unit 110 mills the sample 100 by causing the ion source 102 to irradiate the sample 100 with the FIB 107 according to the conditions set in S501, S503, and S504.

### (S506)

Similarly to S502, the control unit 110 generates a SIM image by irradiating the sample 100 with the FIB 107 and receiving the detection signal from the secondary electron detection unit 106. The SIM image generated in S506 represents the shape of the sample 100 after milling.

### (S507)

The control unit 110 calculates the amount of shape change due to the milling based on the SIM images generated in S502 and S506.

### (S508)

The control unit 110 generates a backscattered electron image by irradiating the sample 100 with the electron beam 108 from the electron source 103 and receiving a detection signal from the backscattered electron detection unit 105 that detects backscattered electrons. The flatness of the milled surface of the sample 100 is reflected in the backscattered electron image.

### (S509)

The control unit 110 calculates the flatness of the milled surface of the sample 100 based on the backscattered electron image generated in S508. The calculated flatness is used for machine training together with the conditions set in S501, S503, and S504 and the amount of shape change calculated in S507.

### (S510)

The control unit 110 determines whether the number of pieces of training data is sufficient. If the number of pieces of training data is sufficient, the processing flow ends, and if not, the processing returns to S501 and S501 to S509 are repeated. At that time, the conditions in S501, S503, and S504 are appropriately changed, and the amount of shape change calculated in S507 and the flatness calculated in S509 are used for machine training.

According to the flow of processing described with reference to FIG. 5, a training model is generated by machine-training the relationship between the milling condition including the tilt angle θ of the milled surface of the sample 100 with respect to the central axis of the FIB 107 and the milling result including the flatness of the milled surface calculated based on the detection signal output from the backscattered electron detection unit 105. By using the generated training model in S206 of FIG. 2, the milling conditions including the tilt angle θ of the milled surface of the sample 100 with respect to the central axis of the FIB 107 can be easily set.

Note that the processing flow in FIG. 5 may be executed for each type of material of the sample 100. That is, the generated training model has the type of the material of the sample 100 as a parameter. Since the training model has the type of the material of the sample 100 as a parameter, milling suitable for the type of the material can be performed. In addition, data stored in advance in a storage unit such as a storage device or a cloud server may be used for machine training. The performance of the training model can be improved by using the data stored in advance in the storage unit for machine training.

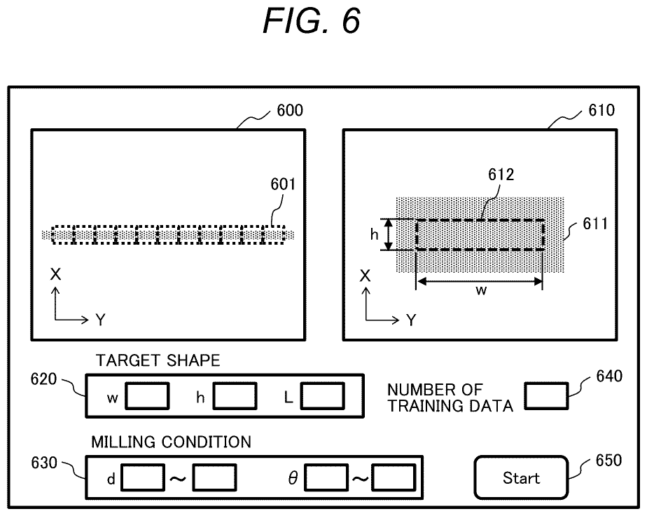

Note that, prior to execution of the flow of processing illustrated in FIG. 5, condition setting related to machine training may be performed using the screen illustrated in FIG. 6. The screen illustrated in FIG. 6 includes a SIM image display unit 600, an enlarged SIM image display unit 610, a target shape input unit 620, a milling condition input unit 630, a training data number input unit 640, and a button 650.

On the SIM image display unit 600, an enlarged region 601 is displayed together with the SIM image of the sample 100. The enlarged region 601 is a region where the enlarged SIM image is generated.

The enlarged SIM image 611 and the target shape 612 are displayed on the enlarged SIM image display unit 610. The enlarged SIM image 611 is an enlarged SIM image generated in the enlarged region 601. The target shape 612 indicates a target shape input by the operator.

The numerical values of the length w in the Y direction, the length h in the X direction, and the length L in the Z direction are input to the target shape input unit 620 as target shapes. The shape of the target shape 612 changes according to the numerical values of w, h, and L input to the target shape input unit 620.

The range of the distance d set in S503 and the range of the tilt angle θ set in S504 are input to the milling condition input unit 630. That is, in the range input to the milling condition input unit 630, the numerical value of the distance d is set in S503, and the numerical value of the tilt angle θ is set in S504. Then, the amount of shape change and the flatness when the sample 100 is milled according to the set numerical values are calculated and used for machine training.

An upper limit value of the number of pieces of training data used for the determination in S510 is input to the training data number input unit 640. That is, when the number of pieces of training data exceeds the upper limit value input to the training data number input unit 640, it is determined in S510 that the number of pieces of training data is sufficient.

When the button 650 is pressed, the flow of processing illustrated in FIG. 5 is executed.

The embodiment of the present invention has been described above. The present invention is not limited to the above embodiments, and can be embodied by modifying the components within the scope not departing from the gist of the invention. In addition, a plurality of components disclosed in the above embodiments may be appropriately combined. Further, some components may be deleted from all the components shown in the above embodiments.

What is claimed is:

1. A charged particle beam device comprising:
a sample holder that holds a sample;
an ion source that emits a focused ion beam with which the sample is irradiated;
a secondary electron detection unit that detects secondary electrons emitted from the sample by irradiation with the focused ion beam; and
a control unit that generates an observation image of the sample based on a detection signal output from the secondary electron detection unit and controls each unit,
wherein
the control unit receives an amount of shape change when the sample is subjected to test milling using the focused ion beam and a target shape after milling of the sample,
the amount of shape change and the target shape are input to a training model generated by performing machine training in advance on a relationship between a milling condition including an tilt angle of a milled surface of the sample with respect to a central axis of the focused ion beam and a milling result including flatness of the milled surface, and
a milling condition including the tilt angle is output.

2. The charged particle beam device according to claim 1, wherein the control unit further sets a distance between a milling region by the focused ion beam and the target shape using the training model.

3. The charged particle beam device according to claim 1, further comprising:
an electron source that emits an electron beam with which the sample is irradiated; and
a backscattered electron detection unit that detects backscattered electrons emitted from the sample by irradiation with the electron beam,
wherein the control unit calculates flatness of the milled surface after being milled by the focused ion beam based on a detection signal output from the backscattered electron detection unit.

4. A control method of a charged particle beam device, the charged particle beam device including
a sample holder that holds a sample,
an ion source that emits a focused ion beam with which the sample is irradiated,
a secondary electron detection unit that detects secondary electrons emitted from the sample by irradiation with the focused ion beam, and
a control unit that generates an observation image of the sample based on a detection signal output from the secondary electron detection unit and controls each unit,
the control method comprising setting an tilt angle by inputting an amount of shape change when the sample is subjected to test milling using the focused ion beam and a target shape after milling of the sample to a training model generated by performing machine training in advance on a relationship between a milling condition including the tilt angle of a milled surface of the sample with respect to a central axis of the focused ion beam and a milling result including flatness of the milled surface.

5. A charged particle beam device comprising:
a sample holder that holds a sample;
an ion source that emits a focused ion beam with which the sample is irradiated;
a secondary electron detection unit that detects secondary electrons emitted from the sample by irradiation with the focused ion beam;
an electron source that emits an electron beam with which the sample is irradiated;
a backscattered electron detection unit that detects backscattered electrons emitted from the sample by irradiation with the electron beam; and
a control unit that generates an observation image of the sample based on a detection signal output from the secondary electron detection unit or the backscattered electron detection unit and controls each unit,
wherein the control unit generates a training model by performing machine training on a relationship between a milling condition including an tilt angle of a milled surface of the sample with respect to a central axis of the focused ion beam and a milling result including flatness of the milled surface calculated based on a detection signal output from the backscattered electron detection unit.

6. The charged particle beam device according to claim 5, wherein the training model has a type of a material of the sample as a parameter.

7. The charged particle beam device according to claim 5, wherein the control unit uses data stored in advance in a storage unit for machine training.
